(19) United States
(12) Patent Application Publication
(10) Pub. No.: US 2014/0367827 A1
(43) Pub. Date: Dec. 18, 2014

(54) METAL CAPACITOR WITH INNER FIRST TERMINAL AND OUTER SECOND TERMINAL

(71) Applicant: QUALCOMM Incorporated, San Diego, CA (US)

(72) Inventors: Bruce Sokki Lee, Irvine, CA (US); Liang Dai, San Diego, CA (US)

(21) Appl. No.: 13/919,790

(22) Filed: Jun. 17, 2013

(51) Int. Cl. H01G 4/228; H01G 13/00; H01L 29/94

(52) U.S. Cl. CPC H01G 4/228; H01L 29/94; H01G 13/006
USPC 257/532; 361/306.1; 29/25.41

(57) ABSTRACT

A metal capacitor with an inner first terminal (e.g., a positive terminal) and an outer second terminal (e.g., a negative terminal) is disclosed herein. In an exemplary design, an apparatus (e.g., an IC chip) includes a first conductive line for a first terminal of a capacitor and at least one conductive line for a second terminal of the capacitor. The at least one conductive line is formed on opposing first and second sides of the first conductive line. Parallel conductive traces are formed transverse to, and on both the first and second sides of, the first conductive line. Additional parallel conductive traces are formed transverse to the at least one conductive line and are interlaced with the parallel conductive traces coupled to the first conductive line. The metal capacitor includes a plurality of unit capacitors formed by the parallel conductive traces coupled to the conductive lines.

### BACKGROUND

I. Field

The present disclosure relates generally to electronics, and more specifically to a capacitor.

II. Background

A capacitor is a circuit component used to store electrical charge from a source and provide the stored electrical charge to other circuit components. Capacitors are commonly used for various circuits such as analog-to-digital converters (ADCs), digital-to-analog converters (DACs), filters, oscillators, phase locked loops (PLLs), etc. A capacitor may be implemented on an integrated circuit (IC) chip. It may be desirable to implement a capacitor in as small an area as possible in order to reduce the size and cost of a device containing the capacitor.

### SUMMARY

A metal capacitor with an inner first terminal (e.g., a positive terminal) and an outer second terminal (e.g., a negative terminal) is disclosed herein. In an exemplary design, an apparatus (e.g., an IC chip) may include a first conductive line for a first terminal of a capacitor and at least one conductive line for a second terminal of the capacitor. The at least one conductive line may be formed on first and second sides of the first conductive line. The second side may be opposite of the first side.

The apparatus may further include conductive traces coupled to the conductive lines. In an exemplary design, parallel conductive traces may be formed transverse to, and on both the first and second sides of, the first conductive line. Additional parallel conductive traces may be formed transverse to the at least one conductive line and may be interlaced with the parallel conductive traces coupled to the first conductive line. The metal capacitor may include a plurality of unit capacitors formed by the parallel conductive traces coupled to the conductive lines.

The first conductive line and the at least one conductive line may be formed on a first metal layer. The apparatus may further include conductive lines formed on one or more other metal layers for the first and second terminals of the capacitor.

Various aspects and features of the disclosure are described in further detail below.

### BRIEF DESCRIPTION OF THE DRAWINGS

FIG. 1 shows a cross-sectional view of an IC chip and metal capacitors formed on metal layers of the IC chip.

FIGS. 2 to 4 show top views of three exemplary designs of a metal capacitor implemented on a metal layer.

FIG. 5 shows a cross-sectional view of an IC chip and metal capacitors with shielding formed on metal layers of the IC chip.

FIG. 6 shows a top view of a metal capacitor with shielding.

FIG. 7 shows a process for forming a capacitor.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

A metal capacitor with an inner first terminal (e.g., a positive terminal) and an outer second terminal (e.g., a negative terminal) is disclosed herein. The metal capacitor may be used for ADCs, DACs, filters, oscillators, PLLs, etc. The metal capacitor may also be used for various electronic devices such as wireless communication devices, personal digital assistants (PDAs), handheld devices, wireless modems, smartphones, laptop computers, smartbooks, netbooks, tablets, cordless phones, wireless local loop (WLL) stations, Bluetooth devices, consumer electronic devices, etc. The metal capacitor may be implemented on an IC chip, a printed circuit board (PCB), etc. For clarity, implementation of the metal capacitor on an IC chip is described below.

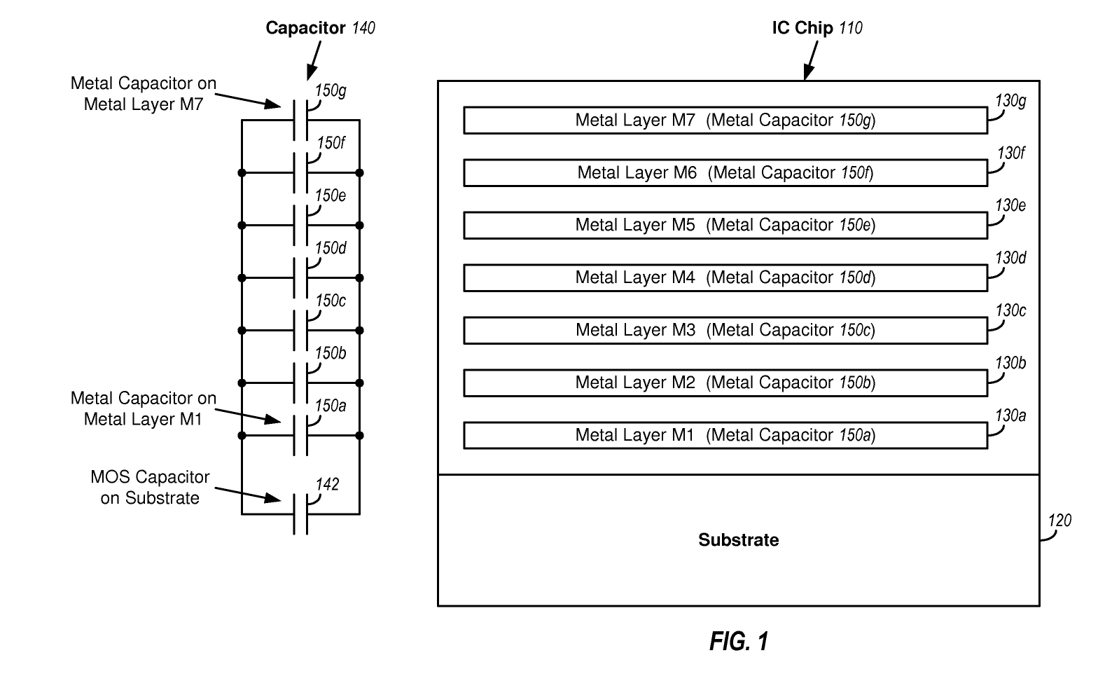

FIG. 1 shows a cross-sectional view of an exemplary design of an IC chip 110 on which a metal capacitor with an inner positive terminal and an outer negative terminal may be implemented. IC chip 110 includes a substrate 120 and seven metal layers 130a to 130g formed over substrate 120. Metal oxide semiconductor (MOS) devices such as MOS transistors may be implemented on substrate 120. Routing traces between the MOS devices may be implemented on multiple metal layers 130a to 130g.

In the exemplary design shown in FIG. 1, metal capacitors 150a to 150g are implemented on metal layers 130a to 130g, respectively. Each metal capacitor 150 may be implemented on one metal layer 130. Metal capacitors 150a to 150g may be coupled in parallel and may have their positive terminals coupled together and their negative terminals coupled together. Metal capacitors 150a to 150g may also be considered as a single metal capacitor implemented on metal layers 130a to 130g.

In an exemplary design, a MOS capacitor 142 may be formed on substrate 120. MOS capacitor 142 may be a regular N-channel MOS (NMOS) capacitor, a regular P-channel MOS (PMOS) capacitor, or an accumulation mode NMOS capacitor. MOS capacitor 142 may be formed under metal capacitor 150a to 150g and may be coupled in parallel with metal capacitors 150a to 150g. For a given area size, a larger capacitor may be obtained with a parallel combination of MOS capacitor 142 and metal capacitors 150. Alternatively, a capacitor of a desired capacitance may be implemented in a smaller area with a parallel combination of MOS capacitor 142 and metal capacitors 150.

An IC process technology may have certain routing preference on each metal layer. For example, it may be preferable to route conductive traces in a horizontal direction on some metal layers (e.g., metal layers M4 and M6) and in a vertical direction on other metal layers (e.g., metal layers M1, M2, M3, M5 and M7). Parallel conductive traces may be placed much closer together when they are routed in the preferred direction. Closer spacing of conductive traces may enable a larger capacitor to be formed due to (i) a higher capacitance between pairs of more closely spaced conductive traces and (ii) a higher density of the conductive traces. The conductive traces may be used for a linear metal capacitor having a capacitance that is largely independent of temperature, voltage, IC process, etc.

In an aspect of the present disclosure, a metal capacitor may be implemented with (i) a center conductive line for a positive terminal and (ii) at least one outer conductive line for a negative terminal. The center conductive line may be formed at or near the center of an area used to implement the metal capacitor. The outer conductive line(s) may be formed on at least two opposing sides of the center conductive line. Parallel conductive traces may be formed on both sides of the center conductive line and transverse to the center conductive line. Parallel conductive traces may also be formed transverse to each outer conductive line. The metal capacitor may comprise a plurality of unit capacitors formed by the conductive traces.

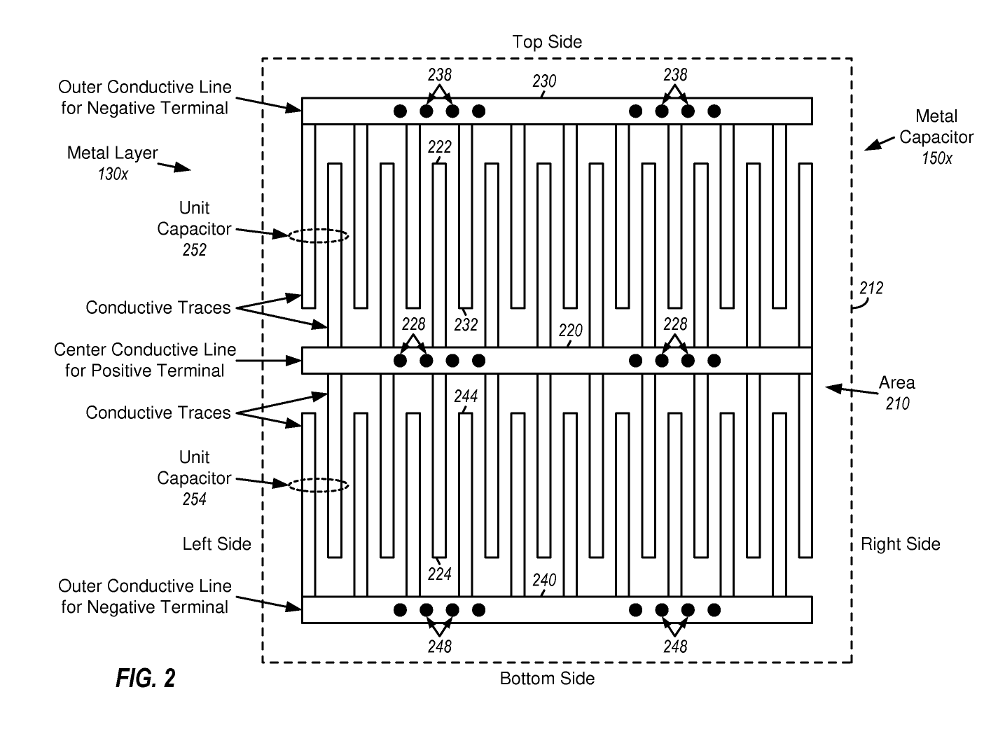

FIG. 2 shows a top view of an exemplary design of a metal capacitor 150x implemented on a metal layer 130x. Metal capacitor 150x may be one of metal capacitors 150a to 150g in FIG. 1. Metal layer 130x may be one of metal layers 130a to 130g for IC chip 110 in FIG. 1. A dashed line 212 shows the boundary of an area 210 in which metal capacitor 150x is implemented. FIG. 2 also shows the four sides of IC chip 110, which includes a top side, a bottom side, a left side, and a right side.

In the exemplary design shown in FIG. 2, metal capacitor 150x comprises (i) a center conductive line 220 for the positive terminal of metal capacitor 150x and (ii) outer conductive lines 230 and 240 for the negative terminal of metal capacitor 150x. A conductive line may also be referred to as a metal line, a trace, a routing trace, a conductive trace, a conductor, etc. Center conductive line 220 is formed in the horizontal direction along the center of area 210. Outer conductive line 230 is formed in the horizontal direction along the top of area 210. Outer conductive line 240 is formed in the horizontal direction along the bottom of area 210.

Parallel conductive traces 222 are formed in the vertical direction and are coupled to the top side of center conductive line 220. The vertical direction is the preferred routing direction for metal layer 130x. Parallel conductive traces 224 are formed in the vertical direction and are coupled to the bottom side of center conductive line 220. Conductive traces 222 and 224 are for the positive terminal of metal capacitor 150x. Parallel conductive traces 232 are formed in the vertical direction and are coupled to the bottom side of outer conductive line 230. Conductive traces 232 are for the negative terminal of metal capacitor 150x and are interlaced with conductive traces 222 for the positive terminal of metal capacitor 150x. Interlacing refers to conductive traces for a first terminal of a capacitor being mixed with conductive traces for a second terminal of the capacitor, so that each conductive trace for the first terminal is adjacent to at least one conductive trace for the second terminal. Parallel conductive traces 244 are formed in the vertical direction and are coupled to the top side of outer conductive line 240. Conductive traces 244 are for the negative terminal of metal capacitor 150x and are interlaced with conductive traces 224 for the positive terminal of metal capacitor 150x.

A unit capacitor 252 is formed by one conductive trace 222 for the positive terminal of metal capacitor 150x and an adjacent conductive trace 232 for the negative terminal of metal capacitor 150x. A number of unit capacitors 252 are formed by conductive traces 222 and 232 and are coupled in parallel. A unit capacitor 254 is formed by one conductive trace 224 for the positive terminal of metal capacitor 150x and an adjacent conductive trace 244 for the negative terminal of metal capacitor 150x. A number of unit capacitors 254 are formed by conductive traces 224 and 244 and are coupled in parallel. Unit capacitors 252 and 254 are coupled in parallel and form metal capacitor 150x.

Interconnections 228 are formed along center conductive line 220 and connect the positive terminal of metal capacitor 150x to other circuit components such as, e.g., other metal capacitors on other metal layers. Interconnections 238 are formed along outer conductive line 230 and connect the negative terminal of metal capacitor 150x to other circuit components. Interconnections 248 are formed along outer conductive line 240 and connect the negative terminal of metal capacitor 150x to other circuit components.

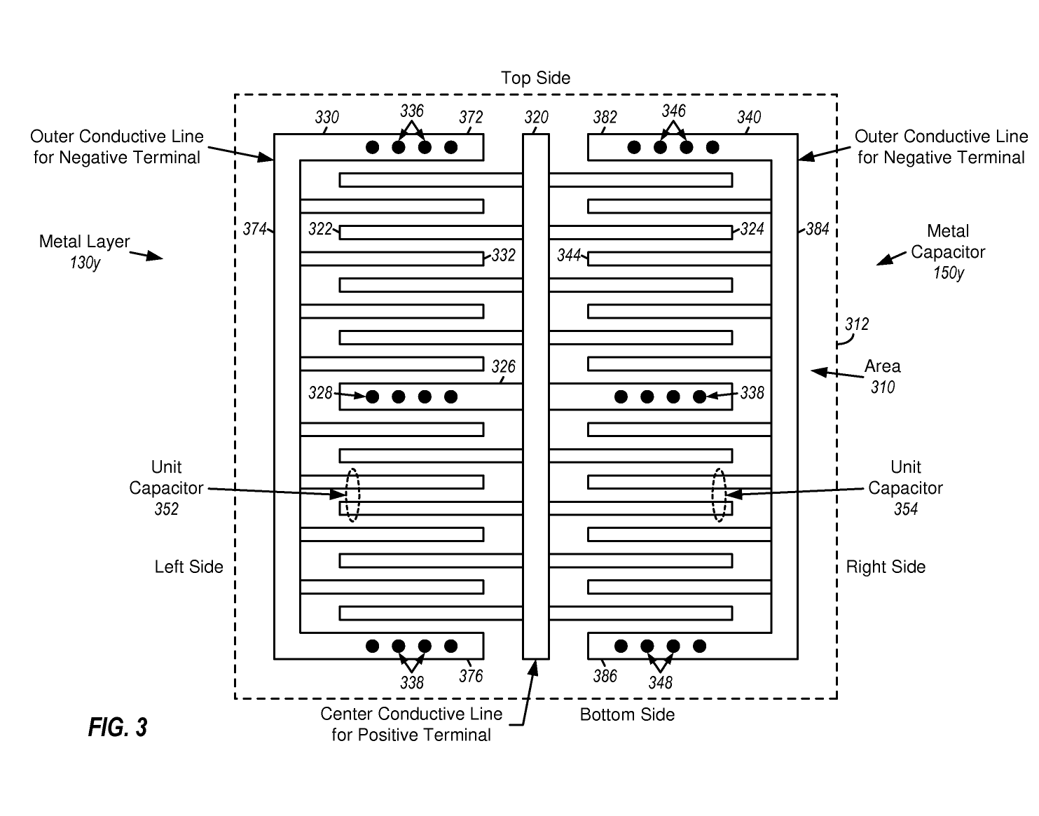

FIG. 3 shows a top view of an exemplary design of a metal capacitor 150y implemented on a metal layer 130y. Metal capacitor 150y may be one of metal capacitors 150a to 150g in FIG. 1. Metal layer 130y may be one of metal layers 130a to 130g for IC chip 110 in FIG. 1. A dashed line 312 shows the boundary of an area 310 in which metal capacitor 150y is implemented. FIG. 3 also shows the four sides of IC chip 110.

In the exemplary design shown in FIG. 3, metal capacitor 150y comprises (i) center conductive lines 320 and 326 for the positive terminal of metal capacitor 150y and (ii) outer conductive lines 330 and 340 for the negative terminal of metal capacitor 150y. Center conductive line 320 is formed in the vertical direction along the center of area 310. Center conductive line 326 is formed in the horizontal direction along the center of area 310 and intersects center conductive line 320. Outer conductive line 330 is formed on the left side of area 310. Outer conductive line 330 has a “C” shape and includes a segment 372 along the top, a segment 374 along the left side, and a segment 376 along the bottom. Outer conductive line 340 is formed on the right side of area 310. Outer conductive line 330 has a reverse “C” shape and includes a segment 382 along the top, a segment 384 along the right side, and a segment 386 along the bottom.

Parallel conductive traces 322 are formed in the horizontal direction and are coupled to the left side of center conductive line 320. The horizontal direction is the preferred routing direction for metal layer 130y. Parallel conductive traces 324 are formed in the horizontal direction and are coupled to the right side of center conductive line 320. Conductive traces 322 and 324 are for the positive terminal of metal capacitor 150y. Parallel conductive traces 332 are formed in the horizontal direction and are coupled to the right side of outer conductive line 330. Conductive traces 332 are for the negative terminal of metal capacitor 150y and are interlaced with conductive traces 322 for the positive terminal of metal capacitor 150y. Parallel conductive traces 344 are formed in the horizontal direction and are coupled to the left side of outer conductive line 340. Conductive traces 344 are for the negative terminal of metal capacitor 150y and are interlaced with conductive traces 324 for the positive terminal of metal capacitor 150y.

A unit capacitor 352 is formed by one conductive trace 322 for the positive terminal of metal capacitor 150y and an adjacent conductive trace 332 for the negative terminal of metal capacitor 150y. A number of unit capacitors 352 are formed by conductive traces 322 and 332 and are coupled in parallel. A unit capacitor 354 is formed by one conductive trace 324 for the positive terminal of metal capacitor 150y and an adjacent conductive trace 344 for the negative terminal of metal capacitor 150y. A number of unit capacitors 354 are formed by conductive traces 324 and 344 and are coupled in parallel. Unit capacitors 352 and 354 are coupled in parallel and form metal capacitor 150y.

Interconnections 328 are formed along center conductive line 326 and connect the positive terminal of metal capacitor 150y to other circuit components such as, e.g., metal capacitor 150x on metal layer 130x and/or other metal capacitors on other metal layers. Interconnections 336 are formed along top segment 372 of outer conductive line 330, and interconnections 338 are formed along bottom segment 376 of outer conductive line 330. Interconnections 346 are formed along top segment 382 of outer conductive line 340, and interconnections 348 are formed along bottom segment 386 of outer conductive line 340. Interconnections 336, 338, 346 and 348 connect the negative terminal of metal capacitor 150y to other circuit components.

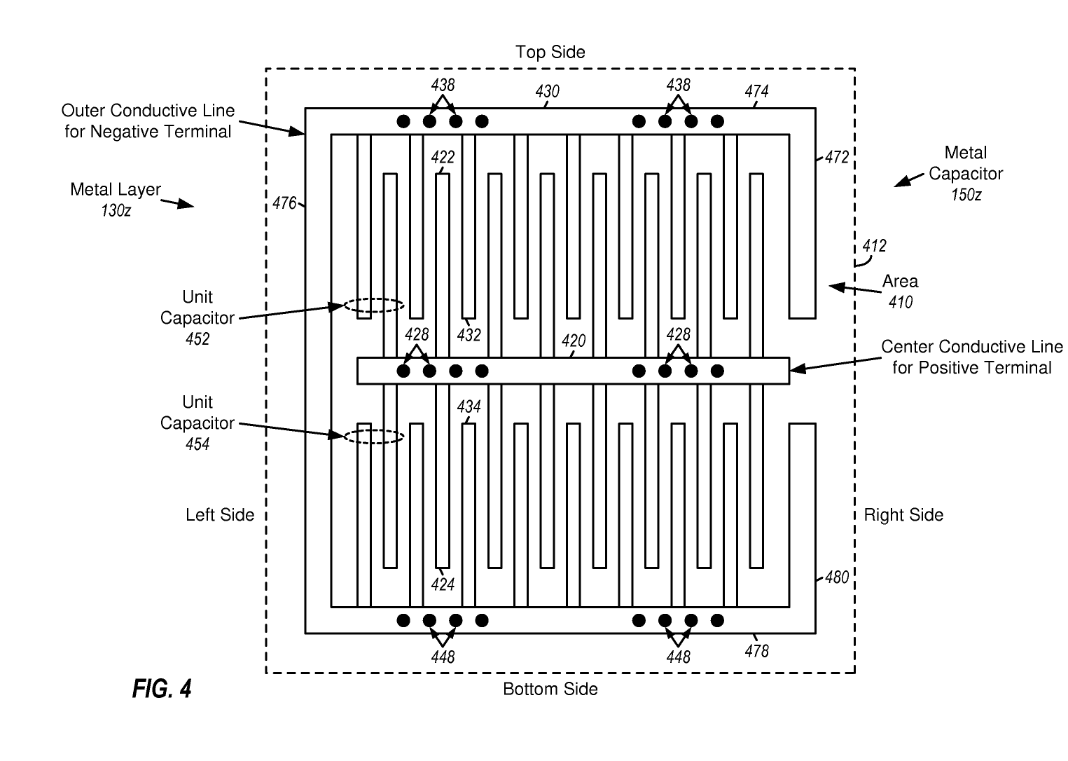

FIG. 4 shows a top view of an exemplary design of a metal capacitor 150z implemented on a metal layer 130z. Metal capacitor 150z may be one of metal capacitors 150a to 150g in FIG. 1. Metal layer 130z may be one of metal layers 130a to 130g for IC chip 110 in FIG. 1. A dashed line 412 shows the boundary of an area 410 in which metal capacitor 150z is implemented. FIG. 4 also shows the four sides of IC chip 110.

In the exemplary design shown in FIG. 4, metal capacitor 150z comprises (i) a center conductive line 420 for the positive terminal of metal capacitor 150z and (ii) an outer conductive line 430 for the negative terminal of metal capacitor 150z. Center conductive line 420 is formed in the horizontal direction along the center of area 410. Outer conductive line 430 is formed along the four sides of area 410. Outer conductive line 430 has a “C” shape and substantially encloses center conductive line 420. Outer conductive line 430 includes a segment 472 along the right side, a segment 474 along the top, a segment 476 along the left side, a segment 478 along the bottom, and a segment 480 along the right side.

Parallel conductive traces 422 are formed in the vertical direction and are coupled to the top side of center conductive line 420. The vertical direction is the preferred routing direction for metal layer 130z. Parallel conductive traces 424 are formed in the vertical direction and are coupled to the bottom side of center conductive line 420. Conductive traces 422 and 424 are for the positive terminal of metal capacitor 150z. Parallel conductive traces 432 are formed in the vertical direction and are coupled to the bottom side of top segment 474 of outer conductive line 430. Parallel conductive traces 434 are formed in the vertical direction and are coupled to the top side of bottom segment 478 of outer conductive line 430. Conductive traces 432 are for the negative terminal of metal capacitor 150z and are interlaced with conductive traces 422 for the positive terminal of metal capacitor 150z. Conductive traces 434 are also for the negative terminal of metal capacitor 150z and are interlaced with conductive traces 424 for the positive terminal of metal capacitor 150z.

A unit capacitor 452 is formed by one conductive trace 422 for the positive terminal of metal capacitor 150z and an adjacent conductive trace 432 for the negative terminal of metal capacitor 150z. A number of unit capacitors 452 are formed by conductive traces 422 and 432 and are coupled in parallel. A unit capacitor 454 is formed by one conductive trace 424 for the positive terminal of metal capacitor 150z and an adjacent conductive trace 434 for the negative terminal of metal capacitor 150z. A number of unit capacitors 454 are formed by conductive traces 424 and 434 and are coupled in parallel. Unit capacitors 452 and 454 are coupled in parallel and form metal capacitor 150z.

Interconnections 428 are formed along center conductive line 420 and connect the positive terminal of metal capacitor 150z to other circuit components such as, e.g., metal capacitor 150x on metal layer 130x, metal capacitor 150y on metal layer 130y, and/or other metal capacitors on other metal layers. Interconnections 436 are formed along top segment 474 of outer conductive lines 430, and interconnections 438 are formed along bottom segment 478 of outer conductive lines 430. Interconnections 436 and 438 connect the negative terminal of metal capacitor 150z to other circuit components.

FIGS. 2 to 4 show three exemplary designs of a metal capacitor with an inner positive terminal and an outer negative terminal. In general, a metal capacitor may include (i) one or more center conductive lines for a positive terminal of the metal capacitor and (ii) one or more outer conductive lines for a negative terminal of the metal capacitor. Each center conductive line may be formed (i) in a horizontal direction or a vertical direction and (ii) at or near the center of an area in which the metal capacitor is implemented. Each outer conductive line may be formed on one or more sides of the area and may have any suitable shape. Parallel conductive traces for the positive terminal of the metal capacitor may be formed transverse to a center conductive line and may be coupled to one or more sides of the center conductive line. Parallel conductive traces for the negative terminal of the metal capacitor may be formed transverse to an outer conductive line and may be coupled to the outer conductive line. Any number of unit capacitors may be formed with the parallel conductive traces for the positive and negative terminals of the metal capacitor.

In general, any number of metal capacitors may be implemented on any number of metal layers. Metal capacitors may be implemented on all (or most) metal layers in order to increase overall capacitor density. The metal capacitors on different metal layers may include center conductive lines and outer conductive lines having the same shape or different shapes. The parallel conductive traces for the positive and negative terminals of the metal capacitors on different metal layers may be (i) in the same direction for all metal layers or (ii) in different directions for different metal layers, e.g., in the vertical direction on one or more metal layers and in the horizontal direction on one or more other metal layers. The metal capacitors on different metal layers may be coupled in parallel to obtain a larger capacitor. The metal capacitors on different metal layers may also be coupled in series, e.g., to form a voltage divider.

In an exemplary design, one or more metal plates may be formed on one or more metal layers and may be used to shield one or more metal capacitors formed on one or more other metal layers. A metal plate may also be referred to as a conductive plate, a shield plate, a ground plate, etc. Shielding may mitigate interference from external sources to the metal capacitors via electro-magnetic coupling and may improve performance.

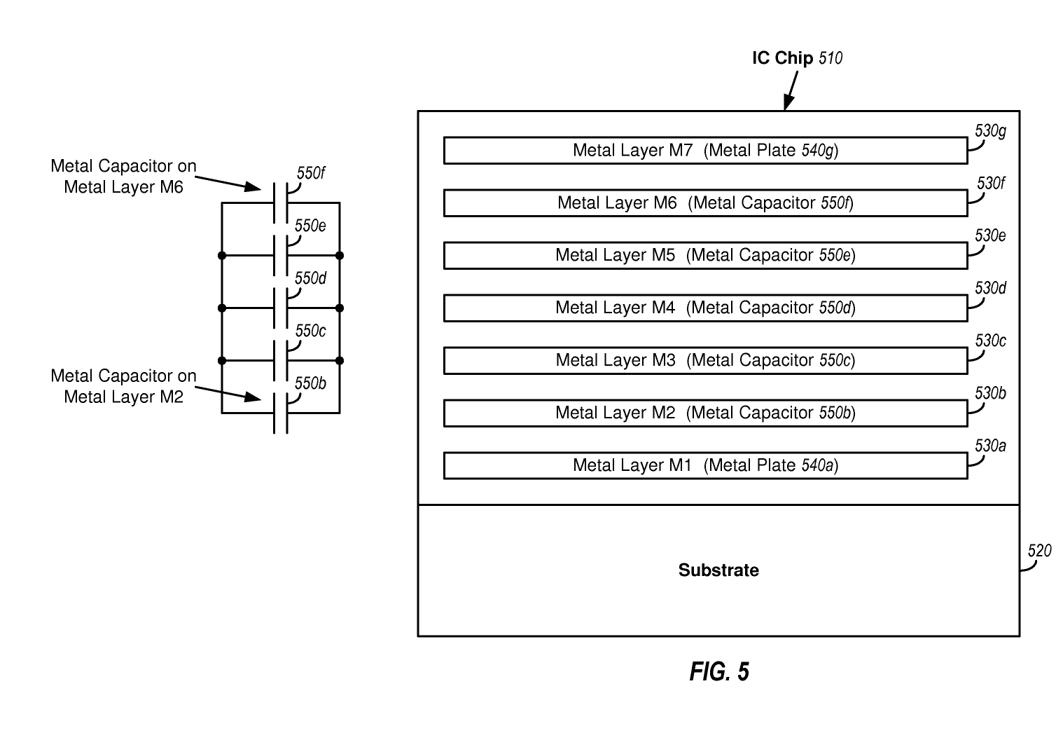

FIG. 5 shows a cross-sectional view of an exemplary design of an IC chip 510 on which one or more metal capacitors with shielding may be implemented. IC chip 510 includes a substrate 520 and seven metal layers 530a to 530g formed over substrate 520. In the exemplary design shown in FIG. 5, metal capacitors 550b to 550f are implemented on metal layers 530b to 530f, respectively. Each metal capacitor 550 may be implemented on one metal layer 530. Metal capacitors 550b to 550f may be coupled in parallel and may have their positive terminals coupled together and their negative terminals coupled together. Metal capacitors 550b to 550f may also be considered as a single metal capacitor implemented on metal layers 530b to 530f.

In an exemplary design, a metal plate 540a may be formed on the bottommost metal layer 530a, and a metal plate 540g may be formed on the topmost metal layer 530g. Metal plates 540a and 540g may each cover an area in which metal capacitors 550b to 550f are formed. In one exemplary design, metal plates 540a and 540g may be coupled to the negative terminals of metal capacitors 550b to 550f. In another exemplary design, metal plates 540a and 540g may be coupled to circuit ground.

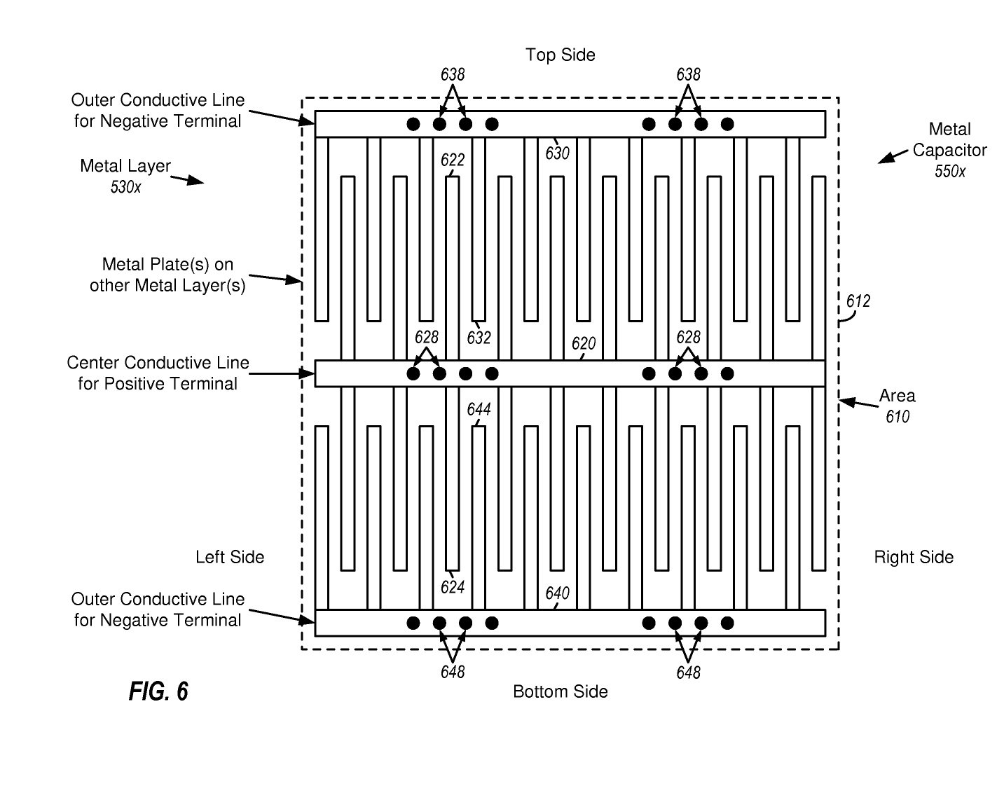

FIG. 6 shows a top view of an exemplary design of a metal capacitor 550x implemented on a metal layer 530x. Metal capacitor 550x may be one of metal capacitors 550b to 550f in FIG. 5. Metal layer 530x may be one of metal layers 530b to 530f for IC chip 510 in FIG. 5. In the exemplary design shown in FIG. 6, metal capacitor 550x comprises a center conductive line 620, outer conductive lines 630 and 640, and conductive traces 622, 624, 632 and 644, which are formed in similar manner as center conductive line 220, outer conductive lines 230 and 240, and conductive traces 222, 224, 232 and 244, respectively, in FIG. 2.

A dashed line 612 shows the boundary of an area 610 in which metal capacitor 550x is implemented. Dashed line 612 may also represent the boundary of metal plates 540a and/or 540g. Interconnections 628 are formed along center conductive line 620 and connect the positive terminal of metal capacitor 550x to other circuit components such as, e.g., other metal capacitors on other metal layers. Interconnections 638 are formed along outer conductive line 630 and connect the negative terminal of metal capacitor 550x to other circuit components and/or metal plates 540a and/or 540g. Interconnections 648 are formed along outer conductive line 640 and connect the negative terminal of metal capacitor 550x to other circuit components and/or metal plates 540a and/or 540g.

In an exemplary design, an apparatus (e.g., an IC chip, a PCB, an electronics device, a wireless device, a circuit module, etc.) may include a first conductive line for a first terminal of a capacitor and at least one conductive line for a second terminal of the capacitor. The at least one conductive line (e.g., conductive lines 230 and 240 in FIG. 2, or conductive lines 330 and 340 in FIG. 3, or conductive line 430 in FIG. 4) may be formed on first and second sides of the first conductive line (e.g., conductive line 220, 320 or 420 in FIG. 2, 3 or 4, respectively). The second side of the first conductive line may be opposite of the first side.

In an exemplary design, the at least one conductive line for the second terminal of the capacitor may comprise (i) a second conductive line (e.g., conductive line 230 or 330) formed on the first side of the first conductive line and (ii) a third conductive line (e.g., conductive line 240 or 340) formed on the second side of the first conductive line. The second conductive line may have a shape that is a mirror image of the shape of the third conductive line. The second and third conductive lines may be parallel straight lines, e.g., as shown in FIG. 2. Alternatively, the second conductive line may have a “C” shape, and the third conductive line having a reverse “C” shape, e.g., as shown in FIG. 3. In another exemplary design, the at least one conductive line for the second terminal of the capacitor may comprise a single conductive line (e.g., conductive line 430 in FIG. 4) formed on the first and second sides of the first conductive line.

The apparatus may further include conductive traces coupled to the conductive lines. A first plurality of conductive traces (e.g., conductive traces 222 in FIG. 2) may be formed transverse to the first conductive line and may be coupled to the first side of the first conductive line. A second plurality of conductive traces (e.g., conductive traces 232) may be formed transverse to the second conductive line, may be coupled to the second conductive line, and may be interlaced with the first plurality of conductive traces. A third plurality of conductive traces (e.g., conductive traces 224) may be formed transverse to the first conductive line and may be coupled to the second side of the first conductive line. A fourth plurality of conductive traces may be formed transverse to the third conductive line, may be coupled to the third conductive line, and may be interlaced with the third plurality of conductive traces.

Each of the first plurality of conductive traces may be adjacent to at least one of the second plurality of conductive traces. A unit capacitor (e.g., unit capacitor 252 in FIG. 2) may be formed by each pair of conductive traces that includes one of the first plurality of conductive traces and one of the second plurality of conductive traces.

The first conductive line and the at least one conductive line may be formed on a first metal layer. The apparatus may further include (i) a second conductive line (e.g., conductive line 320 in FIG. 3) for the first terminal of the capacitor and (ii) at least one additional conductive line (e.g., conductive lines 330 and 340 in FIG. 3) for the second terminal of the capacitor. The second conductive line and the at least one additional conductive line may be formed on a second metal layer. The at least one additional conductive line may be formed on opposite sides of the second conductive line. The second conductive line on the second metal layer may be transverse to the first conductive line on the first metal layer.

The apparatus may further include (i) a third conductive line (e.g., conductive line 420 in FIG. 4) for the first terminal of the capacitor and (ii) one or more additional conductive lines (e.g., conductive line 430) for the second terminal of the capacitor. The third conductive line and the one or more additional conductive lines may be formed on a third metal layer. The one or more additional conductive lines may be formed on opposite sides of the third conductive line. The third conductive line on the third metal layer may be transverse to the second conductive line on the second metal layer and may be parallel with the first conductive line on the first metal layer.

The apparatus may further include various interconnections for the conductive lines. A first plurality of interconnections (e.g., interconnections 238 in FIG. 2) may be located on the first side of the first conductive line and may connect the at least one conductive line on the first metal layer and the at least one additional conductive line on the second metal layer. A second plurality of interconnections (e.g., interconnections 248) may be located on the second side of the first conductive line and may connect the at least one conductive line on the first metal layer and the at least one additional conductive line on the second metal layer.

A fourth conductive line (e.g., conductive line 326 in FIG. 3) for the first terminal of the capacitor may be formed on the second metal layer transverse to the second conductive line. A plurality of interconnections (e.g., interconnections 328) may connect the first conductive line on the first metal layer and the fourth conductive line on the second metal layer.

In an exemplary design, the apparatus may further comprise first and second conductive plate. The first conductive plate (e.g., metal plate 540a in FIG. 5) may be formed on a lower metal layer and may be coupled to the second terminal of the capacitor. The second conductive plate (e.g., metal plate 540g) may be formed on an upper metal layer and may be coupled to the second terminal of the capacitor. The first metal layer may be located between the lower and upper metal layers.

The first conductive line and the at least one conductive line may be formed on one of a plurality of metal layers on an IC chip. A MOS capacitor may be formed on a substrate of the IC chip and may be coupled in parallel with the capacitor.

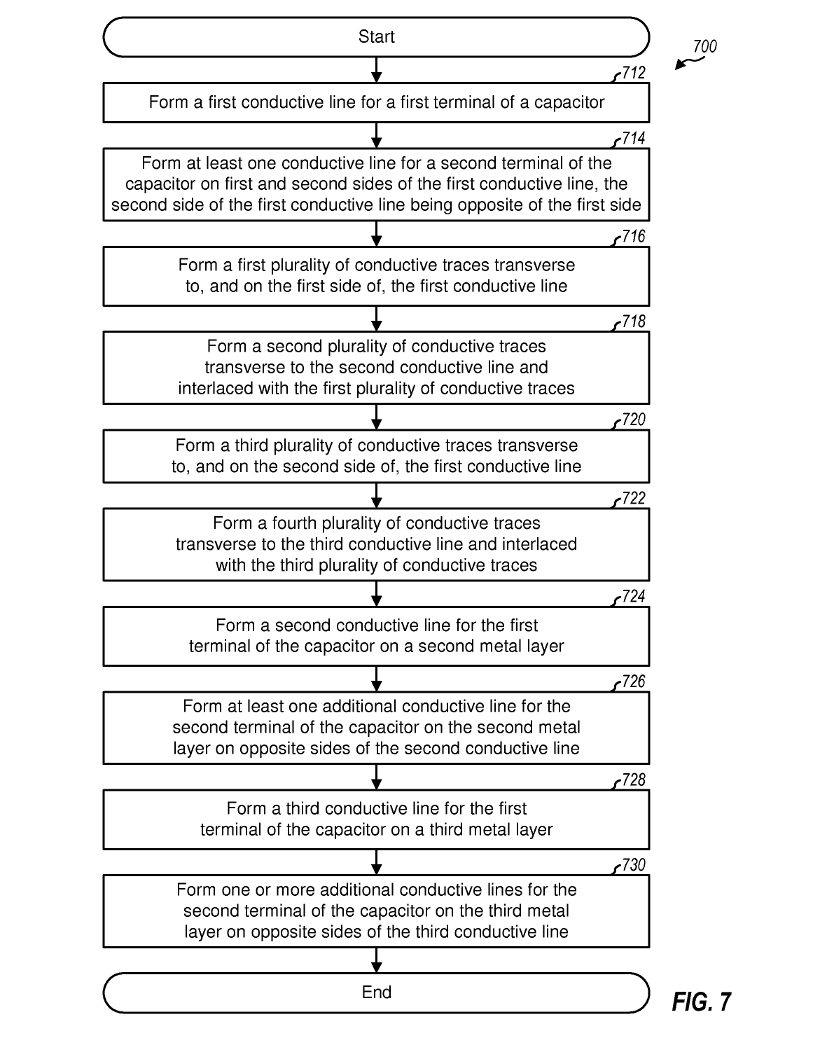

FIG. 7 shows a design of a process 700 for forming a capacitor. A first conductive line for a first terminal of a capacitor may be formed (block 712). At least one conductive line for a second terminal of the capacitor may be formed on first and second sides of the first conductive line (block 714). The second side of the first conductive line may be opposite of the first side.

A first plurality of conductive traces may be formed transverse to, and on the first side of, the first conductive line (block 716). A second plurality of conductive traces may be formed transverse to the second conductive line and may be interlaced with the first plurality of conductive traces (block 718). A third plurality of conductive traces may be formed transverse to, and on the second side of, the first conductive line (block 720). A fourth plurality of conductive traces may be formed transverse to the third conductive line and interlaced with the third plurality of conductive traces (block 722).

The first conductive line and the at least one conductive line may be formed on a first metal layer. A second conductive line for the first terminal of the capacitor may be formed on a second metal layer (block 724). At least one additional conductive line for the second terminal of the capacitor may be formed on the second metal layer on opposite sides of the second conductive line (block 726). The second conductive line on the second metal layer may be transverse to the first conductive line on the first metal layer.

A third conductive line for the first terminal of the capacitor may be formed on a third metal layer (block 728). One or more additional conductive lines for the second terminal of the capacitor may be formed on the third metal layer on opposite sides of the third conductive line (block 730). The third conductive line on the third metal layer may be transverse to the second conductive line on the second metal layer and may be parallel with the first conductive line on the first metal layer.

In an exemplary design, a first conductive plate may be formed on a lower metal layer and may be coupled to the second terminal of the capacitor. A second conductive plate may be formed on an upper metal layer and may be coupled to the second terminal of the capacitor. The first metal layer may be located between the lower and upper metal layers.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus comprising:
a first conductive line (220) for a first terminal of a capacitor (150x); and
at least one conductive line (230, 240) for a second terminal of the capacitor (150x), the at least one conductive line being formed on first and second sides of the first conductive line (220), the second side of the first conductive line (220) being opposite of the first side.

2. The apparatus of claim 1, the at least one conductive line (230, 240) for the second terminal of the capacitor (150x) comprising:
a second conductive line (230) formed on the first side of the first conductive line (220); and
a third conductive line (240) formed on the second side of the first conductive line (220).

3. The apparatus of claim 2, the second conductive line (330) having a “C” shape, and the third conductive line (340) having a reverse “C” shape.

4. The apparatus of claim 2, further comprising:
a first plurality of conductive traces (222) formed transverse to the first conductive line (220) and coupled to the first side of the first conductive line (220); and
a second plurality of conductive traces (232) coupled to the second conductive line (230), the second plurality of conductive traces (232) being formed transverse to the second conductive line (230) and interlaced with the first plurality of conductive traces (222).

5. The apparatus of claim 4, further comprising:
a third plurality of conductive traces (224) formed transverse to the first conductive line (220) and coupled to the second side of the first conductive line (220); and
a fourth plurality of conductive traces (244) coupled to the third conductive line (240), the fourth plurality of conductive traces (244) being formed transverse to the third conductive line (240) and interlaced with the third plurality of conductive traces (224).

6. The apparatus of claim 4, each of the first plurality of conductive traces (222) being adjacent to at least one of the second plurality of conductive traces (232), and a unit capacitor (252) being formed by each pair of conductive traces including one of the first plurality of conductive traces (222) and one of the second plurality of conductive traces (232).

7. The apparatus of claim 1, the at least one conductive line for the second terminal of the capacitor comprising:
a second conductive line (430) formed on the first and second sides of the first conductive line (420).

8. The apparatus of claim 1, the first conductive line and the at least one conductive line being formed on a first metal layer (130x), the apparatus further comprising:
a second conductive line (320) for the first terminal of the capacitor and formed on a second metal layer (130y); and
at least one additional conductive line (330, 340) for the second terminal of the capacitor and formed on the second metal layer (130y) on opposite sides of the second conductive line (320).

9. The apparatus of claim 8, the second conductive line (320) on the second metal layer (130y) being transverse to the first conductive line (220) on the first metal layer (130x).

10. The apparatus of claim 8, further comprising:
a first plurality of interconnections (238) located on the first side of the first conductive line (220) and connecting the at least one conductive line (230) on the first metal layer (130x) and the at least one additional conductive line (330) on the second metal layer (130y); and
a second plurality of interconnections (248) located on the second side of the first conductive line (220) and connecting the at least one conductive line (240) on the first metal layer (130x) and the at least one additional conductive line (340) on the second metal layer (130y).

11. The apparatus of claim 8, further comprising:
a third conductive line (326) for the first terminal of the capacitor and formed on the second metal layer (130y) transverse to the second conductive line (320); and
a plurality of interconnections (328) connecting the first conductive line (220) on the first metal layer (130x) and the third conductive line (326) on the second metal layer (130y).

12. The apparatus of claim 8, further comprising:
a third conductive line (420) for the first terminal of the capacitor and formed on a third metal layer (130z); and
one or more additional conductive lines (430, 440) for the second terminal of the capacitor and formed on the third metal layer (130z) on opposite sides of the third conductive line (420).

13. The apparatus of claim 12, the third conductive line (420) on the third metal layer (130z) being transverse to the second conductive line (320) on the second metal layer (130y) and parallel with the first conductive line (220) on the first metal layer (130x).

14. The apparatus of claim 1, the first conductive line and the at least one conductive line being formed on a first metal layer, the apparatus further comprising:
a first conductive plate (540a) formed on a second metal layer (530a) and coupled to the second terminal of the capacitor; and
a second conductive plate (540g) formed on a third metal layer (530g) and coupled to the second terminal of the capacitor, the first metal layer being located between the second and third metal layers.

15. The apparatus of claim 1, the first conductive line and the at least one conductive line being formed on one of a plurality of metal layers (130a-130g) on an integrated circuit (IC) chip (110).

16. The apparatus of claim 15, further comprising:
a metal oxide semiconductor (MOS) capacitor (142) formed on a substrate (120) of the IC chip (110) and coupled in parallel with the capacitor.

17. A method comprising:
forming (712) a first conductive line for a first terminal of a capacitor; and
forming (714) at least one conductive line for a second terminal of the capacitor on first and second sides of the first conductive line, the second side of the first conductive line being opposite of the first side.

18. The method of claim 17, further comprising:
forming (716) a first plurality of conductive traces transverse to, and on the first side of, the first conductive line; and
forming (718) a second plurality of conductive traces transverse to the second conductive line and interlaced with the first plurality of conductive traces.

19. The method of claim 18, further comprising:
forming (720) a third plurality of conductive traces transverse to, and on the second side of, the first conductive line; and
forming (722) a fourth plurality of conductive traces transverse to the third conductive line and interlaced with the third plurality of conductive traces.

20. The method of claim 17, further comprising:
forming the first conductive line and the at least one conductive line on a first metal layer;
forming (724) a second conductive line for the first terminal of the capacitor on a second metal layer; and
forming (726) at least one additional conductive line for the second terminal of the capacitor on the second metal layer on opposite sides of the second conductive line.

21. The method of claim 20, the second conductive line on the second metal layer being transverse to the first conductive line on the first metal layer.

22. The method of claim 20, further comprising:
forming (728) a third conductive line for the first terminal of the capacitor on a third metal layer; and
forming (730) one or more additional conductive lines for the second terminal of the capacitor on the third metal layer on opposite sides of the third conductive line.

23. The method of claim 22, the third conductive line on the third metal layer being transverse to the second conductive line on the second metal layer and parallel with the first conductive line on the first metal layer.

24. The method of claim 17, further comprising:
forming the first conductive line and the at least one conductive line on a first metal layer;
forming a first conductive plate on a second metal layer; and
forming a second conductive plate on a third metal layer, the first and second conductive plates being coupled to the second terminal of the capacitor, the first metal layer being located between the second and third metal layers.

25. An apparatus for wireless communication, comprising:
means for forming a first conductive line for a first terminal of a capacitor; and
means for forming at least one conductive line for a second terminal of the capacitor on first and second sides of the first conductive line, the second side of the first conductive line being opposite of the first side.

26. The apparatus of claim 25, further comprising:
means for forming a first plurality of conductive traces transverse to, and on the first side of, the first conductive line; and
means for forming a second plurality of conductive traces transverse to the second conductive line and interlaced with the first plurality of conductive traces.

27. The apparatus of claim 26, further comprising:
means for forming a third plurality of conductive traces transverse to, and on the second side of, the first conductive line; and
means for forming a fourth plurality of conductive traces transverse to the third conductive line and interlaced with the third plurality of conductive traces.

28. The apparatus of claim 25, further comprising:
means for forming the first conductive line and the at least one conductive line on a first metal layer;
means for forming a second conductive line for the first terminal of the capacitor on a second metal layer; and
means for forming at least one additional conductive line for the second terminal of the capacitor on the second metal layer on opposite sides of the second conductive line.

29. The apparatus of claim 28, the second conductive line on the second metal layer being transverse to the first conductive line on the first metal layer.

30. The apparatus of claim 28, further comprising:
means for forming a third conductive line for the first terminal of the capacitor on a third metal layer; and
means for forming one or more additional conductive lines for the second terminal of the capacitor on the third metal layer on opposite sides of the third conductive line.

31. The apparatus of claim 30, the third conductive line on the third metal layer being transverse to the second conductive line on the second metal layer and parallel with the first conductive line on the first metal layer.

32. The apparatus of claim 25, further comprising:
means for forming the first conductive line and the at least one conductive line on a first metal layer;
means for forming a first conductive plate on a second metal layer; and
means for forming a second conductive plate on a third metal layer, the first and second conductive plates being coupled to the second terminal of the capacitor, the first metal layer being located between the second and third metal layers.

33. A computer program product, comprising:
a non-transitory computer-readable medium comprising:
code for causing at least one processor to direct formation of a first conductive line for a first terminal of a capacitor; and
code for causing the at least one processor to direct formation of at least one conductive line for a second terminal of the capacitor on first and second sides of the first conductive line, the second side of the first conductive line being opposite of the first side.
